(19) United States
(12) Patent Application Publication
(10) Pub. No.: US 2005/0213306 A1
(43) Pub. Date: Sep. 29, 2005

(54) Environmental control method and apparatus for electronic device enclosures

(75) Inventors: David L. Vos, Apalachin, NY (US); Douglas S. Bendzel, Binghamton, NY (US); David Bittler, Vestal, NY (US); Jonathan M. Brown, Endicott, NY (US)

Correspondence Address: WOLF GREENFIELD & SACKS, PC;FEDERAL RESERVE PLAZA, 600 ATLANTIC AVENUE, BOSTON, MA, 02210-2211, US

(73) Assignee: Lockheed Martin Corporation, Bethesda, MD (US)

(21) Appl. No.: 11/089,673

(22) Filed: Mar. 25, 2005

Related U.S. Application Data
(60) Provisional application No. 60/556,181, filed on Mar. 25, 2004.

(51) Int. Cl. H05K 7/20

(52) U.S. Cl. 361/714; 361/701

(57) ABSTRACT

A method and apparatus for housing electronic components, such as commercial-off-the-shelf (COTS) electronics, in a chamber, or cocoon, so as to protect the components from environmental conditions outside the chamber. In one embodiment, a heat exchanger used to transfer heat between the chamber and its exterior may be incorporated into a wall of the chamber, e.g., located at a sidewall of the chamber. The heat exchanger may use a liquid to transfer heat between the heat exchanger and air in the chamber.

### BACKGROUND OF INVENTION

1. Field of Invention This invention relates to methods and apparatus for environmental control, such as heating and/or cooling, of an environment in an electronic device enclosure or cocoon.

2. Description of Related Art

It is often desirable to use electronic devices, such as computers, data storage devices, etc., in harsh environments. For example, it may be desirable to use such electronic devices in a vehicle, such as an airplane, tank or other, where environmental conditions, e.g., the temperature, humidity, air pressure, vibration, dust or other contaminants, or other conditions, may not be suitable for the proper operation of the devices. The use of commercial off-the-shelf (COTS) devices in military aircraft or other applications may be precluded without providing a proper operating environment for the devices. In some cases, a cocoon or enclosure is provided in which the electronics may be housed and protected, at least in part, from environmental conditions outside the enclosure. Some such enclosures are described, for example in U.S. Pat. No. 6,330,152 and in U.S. Patent Publication 2004/0190229. Such devices protect electronic equipment inside the enclosure from dust, humidity and other environmental factors, while providing heating and/or cooling of the components.

### SUMMARY OF INVENTION

In one aspect of the invention, an electronic device enclosure has walls that define a chamber within which at least one electronic device is located. Thermal conditions within the chamber may be controlled, at least in part, by a heat exchanger that carries a liquid material to transfer heat between the chamber and an environment outside of the enclosure. The liquid material may be circulated through the heat exchanger via an inlet port at which the liquid material flows into the heat exchanger and an outlet port through which the liquid material flows out from the heat exchanger. The liquid material may be provided from a source that is external to and physically separate from the enclosure. By transferring heat (whether cooling or heating) between the chamber and an exterior environment by a liquid material, a volume required to transfer a specific amount of heat may be reduced, e.g., as compared to heating/cooling by air exchange. A high heat capacity/volume ratio may be useful, for example, in environments requiring a compact heating/cooling apparatus. Further, use of a liquid material may allow for more quiet operation (by reducing noise generated by moving air and/or fans), limited or no air exchange with the chamber (such as in pressurized compartments where high volume air exchange may be undesirable), or other.

In one illustrative embodiment, an enclosure for housing electronic devices includes one or more walls, including at least one sidewall, that define a chamber within which electronic devices are located. The chamber may define an environment suitable for the operation of the electronic devices that is different from an environment outside of the chamber. A heat exchanger may be at least partially located in the chamber at a sidewall of the chamber, and use a liquid material to transfer heat between the chamber and an area outside of the chamber. Heat generated by the electronic devices may be transferred by air to the heat exchanger.

In another illustrative embodiment, an enclosure for housing electronic devices includes one or more walls that define a chamber within which electronic devices are located. The chamber may define an environment suitable for the operation of the electronic devices that is different from an environment outside of the chamber. A heat exchanger may be incorporated into at least one wall of the chamber, and use a liquid material to transfer heat between the chamber and an area outside of the chamber. Heat generated by the electronic devices may be transferred by air to the heat exchanger. This arrangement may allow any condensate that forms when cooling the chamber to form at the heat exchanger on the wall or walls, thereby reducing a likelihood that condensate forms at or near electronic components housed in the chamber.

In one embodiment, the chamber may be constructed and arranged so that a fan included with at least one electronic device moves air to cool at least a portion of the electronic device and causes air to move near the heat exchanger. Thus, additional air circulation devices need not be provided for the enclosure since air movement devices that are part of the electronic devices housed in the chamber may provide suitable air movement for cooling purposes.

In another aspect of the invention, a method for providing a suitable environment for electronic devices includes providing an enclosure having walls that define a chamber isolated from external environmental conditions and within which one or more electronic devices are housed. Heat may be transferred from air in the chamber, that is heated by one or more electronic devices, to a liquid material located in a heat exchanger that is incorporated into at least one of the walls of the enclosure.

In one aspect of the invention, a chamber of an electronic device enclosure may be heated and/or cooled without the need for supplying electrical or other power to the enclosure. Instead, the chamber may be heated and/or cooled by passive devices, such as a heat exchanger, without the use of powered pumps, compressors, or other devices at or in the enclosure. Such powered devices, if needed, to cool and/or heat the chamber may be located physically separate from the enclosure, e.g., be part of a vehicle or aircraft in which the enclosure is used.

These and other aspects of the invention will be apparent and/or obvious from the following description. Aspects of the invention may be used separately or in any suitable combination with other aspects of the invention.

### BRIEF DESCRIPTION OF DRAWINGS

Various aspects of the invention are described with reference to the following drawings, wherein like numerals reference like elements, and wherein:

FIG. 1 shows an electronic device enclosure and associated heating/cooling device;

FIG. 2 is a perspective view of a wall of the electronic device enclosure having an integrated heat exchanger;

FIG. 3 is a cross-sectional view of the FIG. 2 wall; and

FIG. 4 is a cross-sectional view of the electronic device enclosure showing an airflow path within the enclosure.

### DETAILED DESCRIPTION

FIG. 1 shows an electronic device enclosure or cocoon 1 within which electronic devices (not shown) may be housed. The electronic devices may be any suitable type of device, such as a general purpose computer, data storage device, data storage media or drive, visual display, printer, etc. The enclosure 1 has a chamber 12 in which at least one electronic device may be housed, e.g., on one or more racks. Once the electronic devices are located within this chamber 12, the enclosure 1 may be closed (e.g., by securing a door (not shown) over the opening to the chamber 12) and optionally sealed from the exterior environment to protect the electronic components from various environmental conditions outside the chamber, such as ambient humidity, temperature, dust, salt spray, or other contaminants, chemicals, air pressure, physical impact, shocks or vibrations, and so on. The chamber may be maintained at a different pressure than the exterior environment, e.g., at a lower or higher pressure than ambient pressure. As is known in the art, electrical and other connections to the electronic devices may be made through input/output ports or other connectors on the enclosure 1 so that communications and/or electrical power may be provided to the electronic devices, etc. Such features are well known in the art and not described in detailed herein.

As shown in FIG. 1, the enclosure 1 has a box-like shape, although the enclosure 1 may have any suitable shape, size, orientation or configuration. The enclosure 1 may have one or more walls 11 that form the chamber 12 within which the electronic devices are housed. Although in this embodiment, the enclosure 1 has only one chamber 12, the enclosure 1 may include two or more chambers, e.g., to provide different environmental conditions for different sets of electronic devices or other objects. Also, the walls 11 that define the chamber are shown in the FIG. 1 embodiment to be exposed (on a side opposite the chamber) to an exterior environment, but such walls 11 may be located within an exterior housing or housings that form part of the enclosure 1. Also, the enclosure 1 may include walls or other structure that define other spaces. Such other spaces may be exposed to the environment around the enclosure (or otherwise have environmental conditions different from that in the chamber 12) and may house an environmental control unit, such as a heat pump, air conditioning unit, pumps, motors, gauges or other indicators, etc.

In one aspect of the invention, a temperature within a chamber of the enclosure may be controlled via heat transfer using a liquid material. This is in contrast to conventional enclosures in which heat is transferred between an enclosure chamber and an exterior environment by air or other gaseous medium (such as an evaporated refrigerant). In the FIG. 1 embodiment, a liquid material, such as water, a glycol solution, oil, or other suitable liquid is provided to the enclosure 1 by a heating/cooling device 2 via inlet and outlet ports 13 and 14 of the enclosure 1. The heating/cooling device 2 (which may heat and/or cool the chamber of the enclosure 1) may take any suitable form. In this illustrative embodiment, the heating/cooling device 2 includes a thermal control unit 21 that is fluidly coupled to the inlet and outlet ports 13, 14 by a supply line 23 and a return line 22. The liquid material may be circulated by a pump or other suitable means (e.g., in the thermal control unit 21), or by gravity. For example, when cooling the chamber of the enclosure 1, the heating/cooling device 2 may provide relatively cool liquid via line 23 to the inlet 13. This liquid may pass through a heat exchanger (not shown) in the enclosure 1 and be warmed by heat in the chamber 12. The heated liquid may exit the outlet 14 and travel via line 22 to the thermal control unit 21, which may cool the liquid, for example, by passing relatively cool air over a finned radiator that carries the liquid. If heating the chamber of the enclosure 1, the heating/cooling device 2 may warm the liquid, e.g., using an electrical resistance heater, waste heat from a vehicle or aircraft engine, etc., and circulate the warmed liquid to the enclosure 1. The heating/cooling device 2 may be part of a vehicle heating/cooling system, e.g., be part of a system that is used to heat/cool other vehicle portions. The heated liquid from enclosure 1 may also be routed to a large capacity heat sink, e.g., a liquid-to-liquid heat exchanger located in the fuel tank to exchange heat into a large quantity of fuel without a significant rise in fluid temperature.

The air temperature in the chamber may be controlled in any suitable way, such as by a sensor in the chamber that provides temperature information to the heating/cooling device 2. Based on this information, the heating/cooling device 2 may control operation of various components to adjust or maintain the temperature in the chamber, e.g., by activating a circulation pump, heater, cooling device, fans, etc.

In one aspect of the invention, the chamber of an enclosure may be heated and/or cooled by means of a passive device at the enclosure. That is, power need not be supplied to the enclosure to heat and/or cool the chamber. Rather, a passive device, such as a passive heat exchanger, may be used. As shown in FIG. 1, the chamber 12 of the enclosure 1 may be heated and/or cooled by providing suitable liquid at the inlet/output ports 13, 14. No power need be supplied to the enclosure 1 to perform the heating and/or cooling. Instead, any power required to perform the heating and/or cooling may be provided to the heating/cooling device 2, e.g., to power pumps, refrigerant compressors, heat pumps, etc. Such an arrangement may reduce the power load required to operate the enclosure 1, for example, if the heating/cooling device 2 is incorporated as part of a vehicle system that heats and/or cools multiple enclosures 1. For example, an aircraft may have multiple enclosures 1 or other aircraft components or spaces that are heated/cooled by a common heating/cooling system 2. This heating/cooling system 2 may circulate a liquid material to the enclosures 1 to remove heat from the chambers thereof, and cause the warmed liquid material to travel to a heat exchanger located elsewhere within the aircraft, e.g., cooled by outside air, used to heat other portions of the vehicle, or utilize the fuel tanks to moderate liquid temperatures.

In another aspect of the invention, a heat exchanger used to heat and/or cool a chamber of an enclosure may be incorporated into at least a part of a wall, such as a sidewall, that forms the chamber. Such an arrangement may reduce the weight of the enclosure by allowing at least a part of the heat exchanger to form part of the structure of the enclosure. Such an arrangement may also reduce the size of the enclosure and/or reduce its complexity, such as when assembling the enclosure. In addition, locating a heat exchanger at a wall of a chamber may provide a more suitable location for condensation to occur, particularly when cooling a chamber. For example, when cooling electronic components by supplying cool air into the enclosure, condensation may occur at or near electronic components, possibly forming unwanted pools of water near the components. By cooling the chamber via heat exchangers at the walls of the chamber, condensation may form at the walls, away from the electronic devices. With a heat exchanger incorporated into one of the sidewalls of the enclosure, i.e., one of the walls that has a vertically oriented portion, condensate can be channeled to drain to a suitable collection point and/or away from the electronic devices, such as near the bottom of the enclosure.

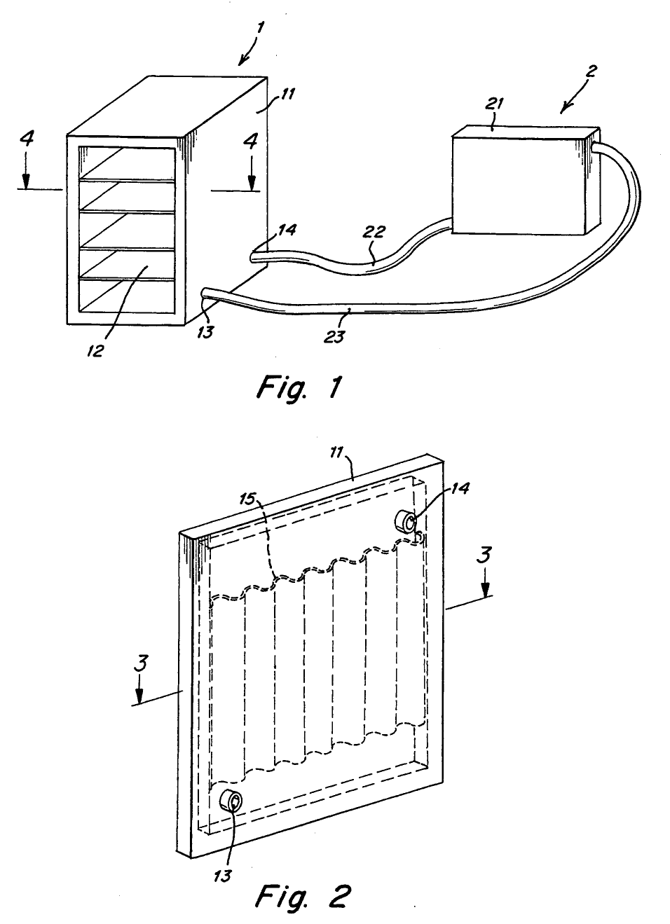

FIG. 2 shows a perspective view of a wall 11 that is part of the enclosure 1 in FIG. 1. In this illustrative embodiment, a heat exchanger 15 is incorporated with the wall 11, and liquid may be supplied at the inlet 13 and pass through one or more channels or pathways of the heat exchanger 15 to the outlet 14. Although the heat exchanger 15 in this embodiment is shown as having a single curving pathway, the heat exchanger 15 may have any suitable arrangement. Moreover, the heat exchanger 15 may communicate with two or more inlets and/or two or more outlets.

FIG. 3 shows a cross-sectional view of the wall 11 along the line 3-3 in FIG. 2. In this illustrative embodiment, the heat exchanger 15 is formed by spacing two flat panels a suitable distance apart to form heat exchanger pathways between the plates, arranging fins or other members on the wall 11 to enhance heat transfer, and arranging a corrugated panel 16 adjacent a flat panel to form heat exchanger pathways in the spaces between the corrugated member and the flat member (as well as to provide additional strength to the wall 11). Of course, it will be understood that the particular arrangement shown in FIGS. 2 and 3 is only one illustrative embodiment. The integrated heat exchanger/wall may be formed in any suitable way, such as by forming U-shaped pathways integrally with the wall members. These pathways may be molded or extruded with the wall member to form a unitary structure, or may be formed by U-shaped channels that are welded or otherwise fixed to the wall member. The wall 11 with incorporated heat exchanger 15 may be formed of a single material, such as aluminum or other suitable metal, plastic or composite, or may be made from a combination of materials, such as a combination of composites, metals and/or plastics, etc.

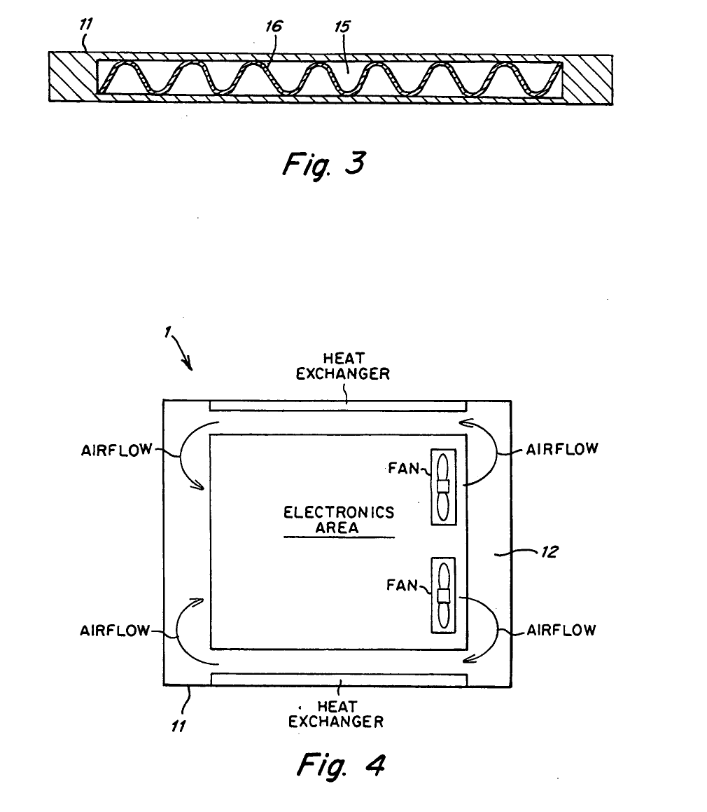

In another aspect of the invention, a chamber of an enclosure may be cooled by air circulation within the chamber in conjunction with a passive heat exchanger. For example, as shown in FIG. 4, electronics within a chamber 12 of an enclosure 1 may be cooled by circulating air, e.g. via one or more fans, such that air passes near or through electronic devices and subsequently passes near or through a heat exchanger to transfer heat between the electronic devices and the heat exchanger. For example, existing fans in the electronic devices, such as fans within a computer housing, may draw relatively cool air into the electronic device and exhaust relatively warm air. This air movement may cause a circulating flow such that relatively warm air exhausted by an electronic device passes near or through a heat exchanger to be cooled. However, since air is not exchanged with the environment outside the chamber 12, the electronic devices within the chamber 12 remain relatively protected from environmental conditions, such as humidity, air pressure, dust, salt spray, or other contaminants, etc.

Thus, in one aspect of the invention, heating and/or cooling of electronic devices may be performed using air moving devices that are pre-existing in the electronic devices and without having to provide additional air moving devices in the enclosure 1. Accordingly, the enclosure 1 may have a passive heating and/or cooling system such that no powered devices need be provided with the enclosure 1 to perform heating and/or cooling of the electronic devices. Instead, the electronic devices may be powered as normally required and the fans or other air moving devices that are part of the electronic devices may be used to perform the desired air circulation within the chamber. As a result, the enclosure 1 need not be specially equipped to provide certain air volume flow rates, air flow speeds or other requirements specific to the electronic devices in the enclosure 1. Instead, the fans, or other air moving devices that are incorporated into the electronic devices may be relied upon to provide the needed airflow or other cooling/heating characteristics for the specific electronic device.

Aspects of the invention are particularly suitable for employing electronic devices, such as COTS devices, in vehicles, e.g., military or other aircraft, wheeled or tracked vehicles, boats and ships, rail cars, etc. The electronic device enclosures can be arranged to work with existing heating/cooling systems in a vehicle and to protect electronic or other devices from environments encountered in or on a vehicle.

While aspects of the invention have been described with reference to various illustrative embodiments, the invention is not limited to the embodiments described. Thus, it is evident that many alternatives, modifications, and variations of the embodiments described will be apparent to those skilled in the art. Accordingly, embodiments of the invention as set forth herein are intended to be illustrative, not limiting. Various changes may be made without departing from the invention.

1. An enclosure for housing electronic devices comprising:
one or more walls, including at least one sidewall, that define a chamber within which electronic devices are located, the chamber having an environment suitable for the operation of the electronic devices and that is different from an environment outside of the chamber; and
a heat exchanger at least partially located in the chamber at a sidewall of the chamber, the heat exchanger using a liquid material to transfer heat between the chamber and an area outside of the chamber, wherein heat generated by the electronic devices is transferred by air to the heat exchanger.

2. The enclosure of claim 1, wherein:
the heat exchanger is integrally formed with at least one sidewall.

3. The enclosure of claim 1, wherein a portion of the heat exchanger forms a portion of the sidewall of the enclosure.

4. The enclosure of claim 1, wherein condensate formed on the heat exchanger in the chamber is channeled to a bottom of the enclosure.

5. The enclosure of claim 1, wherein the chamber is sealed from an exterior environment to protect the electronic components from exterior environmental conditions outside the chamber.

6. The enclosure of claim 5, wherein the exterior environmental conditions include ambient humidity, temperature, dust, chemicals, air pressure, physical impact, or vibration.

7. The enclosure of claim 1, further comprising at least one connection between at least one device outside of the chamber and at least one electronic device in the chamber.

8. The enclosure of claim 1, wherein the enclosure is constructed and arranged to be located in or on a vehicle, the vehicle being a fixed wing aircraft, a rotary wing aircraft, a wheeled vehicle, a track vehicle, or a boat.

9. The enclosure of claim 1, wherein the chamber is constructed and arranged so that a fan included with at least one electronic device moves air to cool at least a portion of the electronic device and causes air to move near the heat exchanger.

10. An enclosure for housing electronic devices comprising:
one or more walls that define a chamber within which electronic devices are located, the chamber having an environment suitable for the operation of the electronic devices and that is different from an environment outside of the chamber; and
a heat exchanger incorporated into at least one wall of the chamber, the heat exchanger using a liquid material to transfer heat between the chamber and an area outside of the chamber, wherein heat generated by the electronic devices is transferred by air to the heat exchanger.

11. The enclosure of claim 10, wherein the one or more walls includes at least one sidewall, and a portion of the heat exchanger forms a portion of a sidewall of the enclosure.

12. The enclosure of claim 10, wherein condensate formed on the heat exchanger in the chamber is channeled to a bottom of the enclosure.

13. The enclosure of claim 10, wherein the chamber is sealed from an exterior environment to protect the electronic components from exterior environmental conditions outside the chamber.

14. The enclosure of claim 10, wherein the liquid material is a single-phase liquid material.

15. The enclosure of claim 10, further comprising at least one connection between at least one device outside of the chamber and at least one electronic device in the chamber, the at least one connection providing electric power or communications.

16. The enclosure of claim 10, wherein the enclosure is constructed and arranged to be located in or on a vehicle, the vehicle being a fixed wing aircraft, a rotary wing aircraft, a wheeled vehicle, a track vehicle, rail car, or a boat; and
wherein heat transferred to the liquid material is subsequently transferred from the liquid material to a portion of the vehicle.

17. The enclosure of claim 16, wherein heat is transferred from the liquid material to contents of a fuel tank.

18. The enclosure of claim 10, wherein the chamber is constructed and arranged so that a fan included with at least one electronic device moves air to cool at least a portion of the electronic device and causes air to move near the heat exchanger.

19. A method for providing a suitable environment for electronic devices, comprising:
providing an enclosure having walls that define a chamber isolated from external environmental conditions and within which one or more electronic devices are housed; and
transferring heat from air in the chamber heated by one or more electronic devices to a liquid material located in a heat exchanger that is incorporated into at least one of the walls of the enclosure.

20. The method of claim 19, further comprising:
moving heated air in or near an electronic device to a location near the heat exchanger using a fan that is part of the electronic device.
